(19) United States
(12) Patent Application Publication
(10) Pub. No.: US 2014/0202533 A1
(43) Pub. Date: Jul. 24, 2014

(54) THERMOPLASTIC POLYOLEFIN COPOLYMER LAMINATION FILM, LAMINATED STRUCTURES AND PROCESSES FOR THEIR PREPARATION

(71) Applicants: John D. Weaver, Pearland, TX (US); Shaofu Wu, Sugar Land, TX (US); Joseph Dooley, Midland, MI (US); William J. Harris, Lake Jackson, TX (US); Chang Dong Lee, Midland, MI (US)

(72) Inventors: John D. Weaver, Pearland, TX (US); Shaofu Wu, Sugar Land, TX (US); Joseph Dooley, Midland, MI (US); William J. Harris, Lake Jackson, TX (US); Chang Dong Lee, Midland, MI (US)

(73) Assignee: DOW GLOBAL TECHNOLOGIES LLC, Midland, MI (US)

(21) Appl. No.: 13/996,226

(22) PCT Filed: Nov. 7, 2011
(86) PCT No.: PCT/US11/59657

§ 371 Date: Jan. 31, 2014

Related U.S. Application Data
(60) Provisional application No. 61/425,549, filed on Dec. 21, 2010.

(51) Int. Cl. H01L 31/048; B32B 27/08; B32B 27/32

(52) U.S. Cl. CPC H01L 31/0481; B32B 27/327; B32B 27/08
USPC 136/259; 428/218; 428/429; 428/447; 525/333.7; 525/333.9; 156/60

(57) ABSTRACT

Disclosed are polyolefin copolymer films comprising alkoxysilane groups and a catalyst for cross-linking the alkoxysilane groups; wherein the cross-linking catalyst is a Lewis or Bronsted acid or base compound that has a relatively high melting point and therefore initiates the cross-linking essentially only at the lamination temperature, preferably at or above at least 50° C. Also disclosed are films wherein (i) the layer or layers comprising the alkoxysilane groups, including surface layer(s), comprise the cross-linking catalyst; or (ii) layer or layers comprising alkoxysilane groups do not contain cross-linking catalyst and have a facial surface in adhering contact with a layer of a thermoplastic polyolefin copolymer comprising the cross-linking catalyst; or (iii) there is a combination of layers (i) and (ii). Also disclosed are laminated glass structures and processes for their preparation that employ such films. The disclosed laminate structures include safety glass and photovoltaic modules.

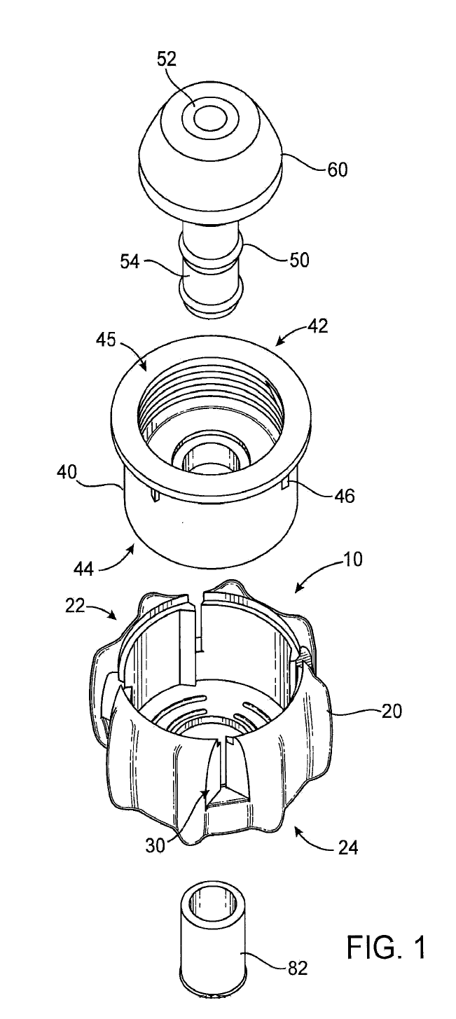

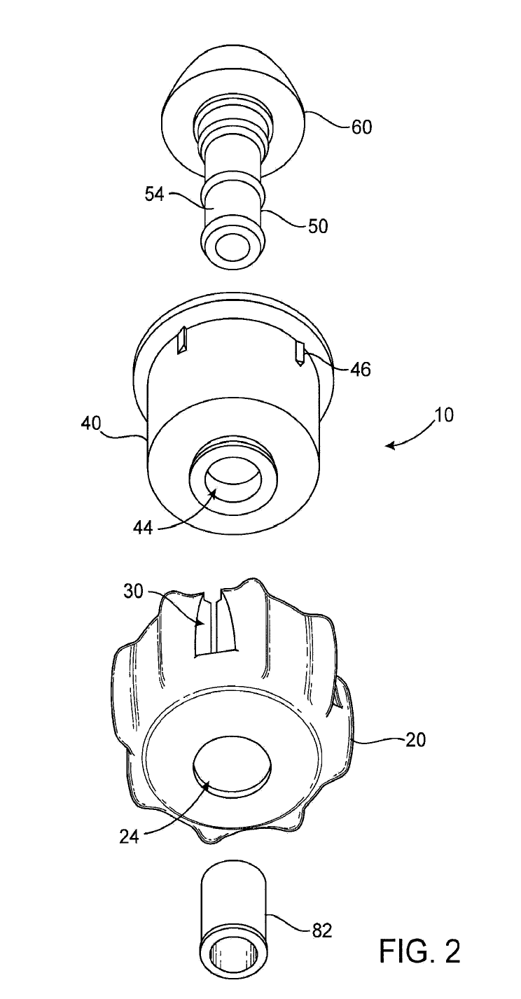

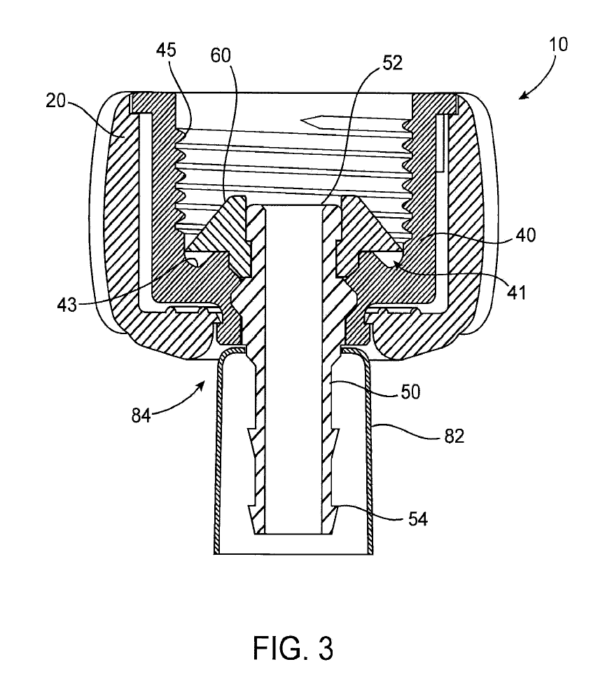

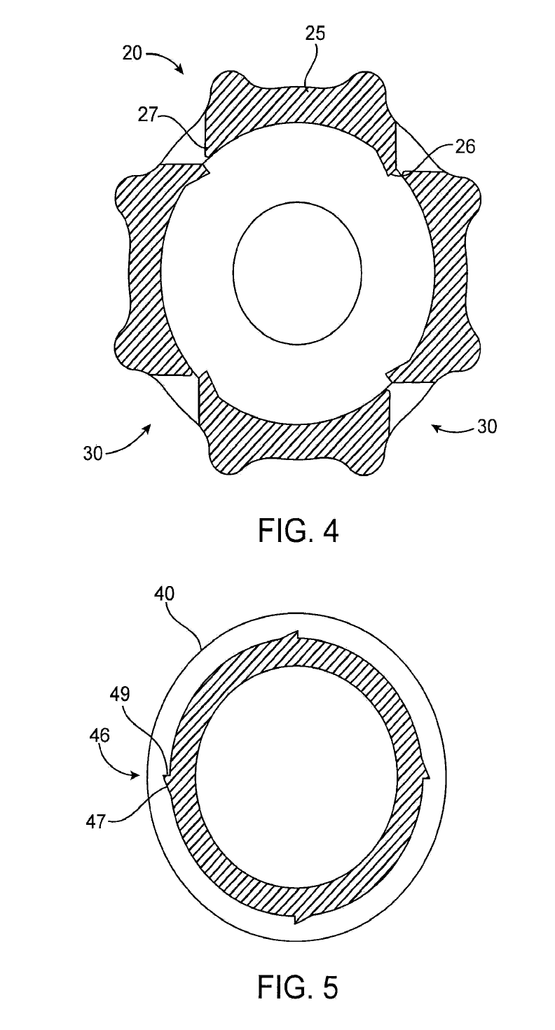

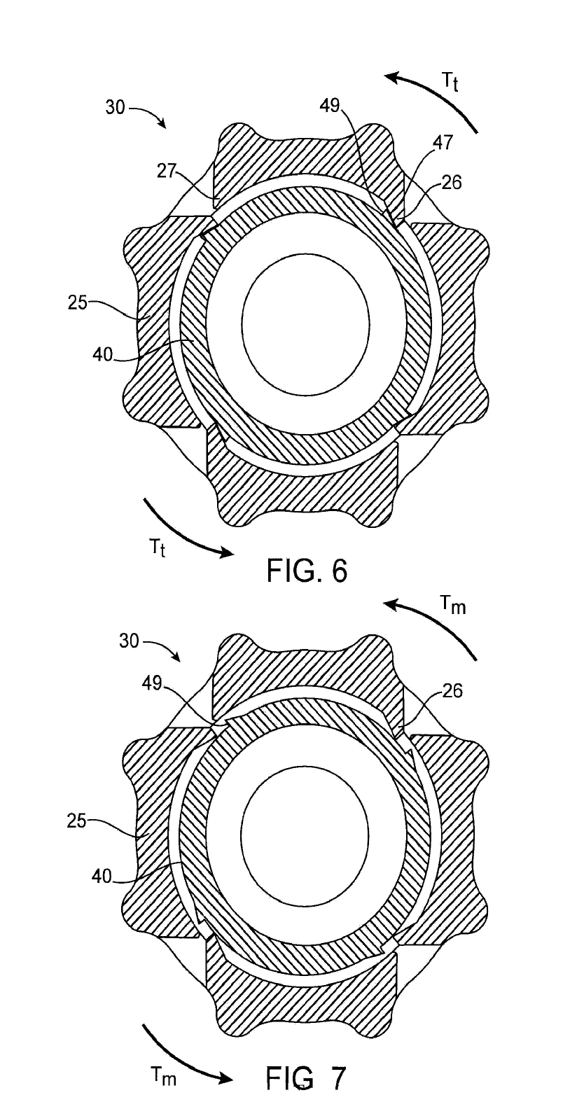

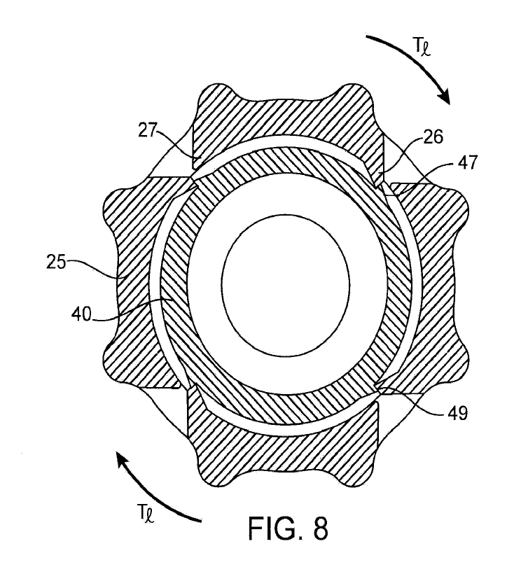

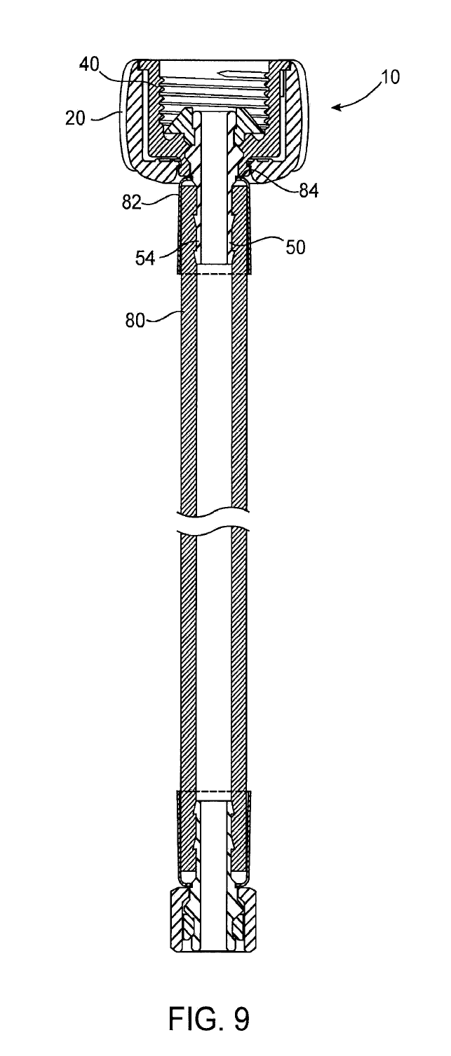

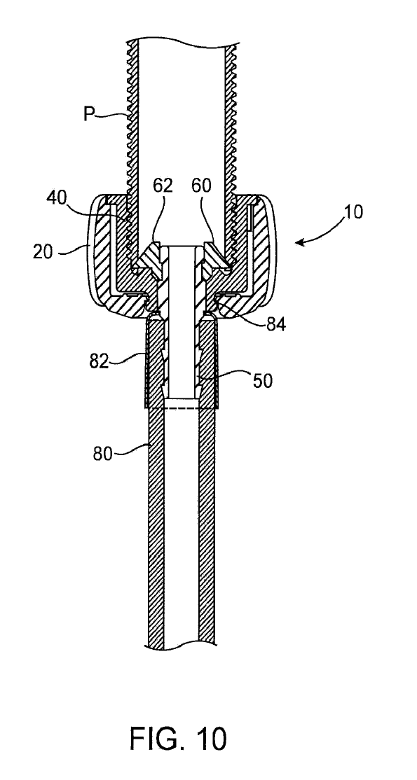

### CROSS-REFERENCE TO RELATED APPLICATIONS

This application claims priority from provisional application Ser. No. 61/425,549, filed Dec. 21, 2010, which is incorporated herein by reference in its entirety.

### FIELD OF THE INVENTION

This invention relates to thermoplastic polyolefin copolymer films, including laminated structures and processes for their preparation that employ such films. In one aspect, the invention relates to photovoltaic modules comprising a photovoltaic cell, a surface layer, such as glass, and at least one thermoplastic polyolefin copolymer film layer. In still another aspect, the invention relates to a method of making a laminated structure in which a thermoplastic polyolefin copolymer film is in adhering contact with glass or other layer while in yet another aspect, the invention relates to a method making a laminated structure in which the thermoplastic polyolefin copolymer film is both silane-crosslinked and exhibits good adhesion to adjacent layers, such as glass.

### BACKGROUND OF THE INVENTION

It is known that laminated structures such as, for example, safety glass and photovoltaic (“PV”) modules, frequently use a plastic film layer to adhere the glass and/or other layers and, in the case of PV modules, as encapsulation layers to adhere the interior photovoltaic cell to other layers, and encapsulate the PV cell to protect it from moisture and other types of physical damage. Optical clarity, good physical and moisture resistance properties, moldability and low cost are among the desirable qualities for such films. The incorporation of alkoxysilane into a thermoplastic polyolefin film has been found to provide both improved adhesion properties in the thermoplastic polyolefin copolymer, particularly to glass, and crosslinking that provides, in turn, the thermoplastic polyolefin copolymer with improved physical properties. However, it has been found that while the silane-crosslinked thermoplastic polyolefin has very good mechanical strength at elevated temperatures, when it is crosslinked, it exhibits less adhesion than if not cross-linked. It is believed that cross-linking the alkoxysilane groups on the surface of the film reduces the number available for reaction with and adhesion to the glass or other surface, and generally reduces the moldability.

WO 2010/009017 discloses laminated structures comprising a (i) glass layer and (ii) laminate film structures having first and second alkoxysilane-containing polyolefin (thermoplastic polyolefin) layers with an interior cross-link catalyst layer sandwiched between and contacting each of the first and second alkoxysilane-containing thermoplastic polyolefin layers. Thus, locating the cross-link catalyst in the layer adjacent to the thermoplastic polyolefin copolymer is intended to delay the cross-linking until the surface of the thermoplastic polyolefin copolymer adjacent to glass has sufficiently adhered to the glass. However, it has been found that, in some fashion, the alkoxysilane-containing thermoplastic polyolefin disclosed apparently crosslinks prematurely at or near the surface to a limited degree and still reduces the glass adhesion properties.

For these and other reasons, there is continuing need in the industry for improvements in alkoxysilane-containing thermoplastic polyolefin copolymers, laminated thermoplastic polyolefin copolymer films, and laminated glass/polyolefin film laminated structures, such as PV panels to obtain improved combinations of thermoplastic polyolefin copolymer glass adhesion and cross-linking.

### BRIEF SUMMARY OF THE INVENTION

Therefore, according to the present invention, there are provided several alternative embodiments or variations. One such embodiment is a lamination film comprising: (a) a facial surface layer comprising an alkoxysilane-containing thermoplastic polyolefin copolymer and (b) a catalyst for crosslinking the alkoxysilane groups that consists essentially of is a Lewis or Bronsted acid or base compound having a melting point greater than the typical maximum ambient temperature of film handling, transportation, and storage and at least about 5° C. less than the temperature for lamination of the film layer. In other embodiments, in such films, independently or in combination:

(1) the crosslinking catalyst has a melting point of at least 50° C.;
(2) effective crosslinking catalysis occurs primarily at lamination temperature conditions and not at lower temperatures;
(3) the crosslinking catalyst has a chemical structure represented by one or more of the following:

(a) R—SO₃H,

(b) R₂Sn^{IV}(OZ)₂,

(c) [R₂Sn^{IV}(OZ)]₂O,

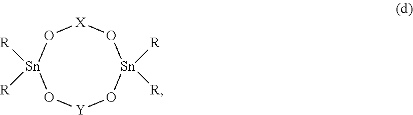

(e) R¹R²R³R⁴Ti^{IV}, or

(f) R¹R²R³R⁴Zr^{IV};

where each R is independently a monovalent hydrocarbon group with from 1 to 24 carbon atoms, each R¹, R², R³, and R⁴ are independently selected from monovalent alkoxy, aryloxyl, or carboxyl groups with from 1 to 24 carbon atoms, X and Y are independently selected from divalent alkoxy, aryloxyl, or carboxyl groups with from 1 to 6 carbon atoms, and Z is an organic group with from 1 to 24 carbon atoms having a functional group that can form a coordinate bond with Sn;

(4) the cross-linking catalyst is represented by formulae (b) or (c); and/or
(5) the cross-linking catalyst is one or more compound selected from the group consisting of: 1,3-diacetoxy-1,1,3,3-tetrabutyldistannoxane and dibutyltin maleate.

Other embodiments include a film having one or more of the above characteristics and:

(6) having at least two thermoplastic polyolefin copolymer layers wherein prior to lamination: A. the film comprises at least one thermoplastic polyolefin copolymer surface layer comprising the alkoxysilane groups; and B. regarding the crosslinking catalyst: (i) the layer or layers comprising the alkoxysilane groups, including surface layer(s), comprise the crosslinking catalyst; or (ii) layer or layers comprising alkoxysilane groups do not contain crosslinking catalyst and have a facial surface in adhering contact with a layer of a thermoplastic polyolefin copolymer comprising the crosslinking catalyst; or (iii) there is a combination of layers (i) and (ii);
(7) comprising two alkoxysilane-containing surface layers according to (ii) which do not contain crosslinking catalyst and each have an interior facial surface in adhering contact with a facial surface of a catalyst-containing layer;
(8) wherein the crosslinking catalyst and alkoxysilane groups are not in the same layers and are in separate alternating layers that have facial surfaces in adhering contact and the film comprises at least 5 total layers;
(9) wherein the thermoplastic polyolefin copolymer in the alkoxysilane-containing layers is a thermoplastic polyolefin copolymer grafted with alkoxysilane compound, and the polyolefin copolymer is an ethylene/α-olefin copolymer that, before grafting, has a density less than 0.93 g/cm3 and a melt index less than 75 g/10 min;
(10) also comprising catalyst-containing layer(s) that are an ethylene/α-olefin copolymer that has a density less than 0.93 g/cm3 and a melt index less than 75 g/10 min; and/or
(11) wherein the film comprises a layer comprising from about 0.001 to about 0.01 weight percent crosslinking catalyst.
Other alternative embodiments related to these films include:
(12) a laminated structure comprising: (i) at least one top layer and (ii) at least one film as described above;
(13) a laminated structure of in the form of a PV module, safety glass or insulated glass comprising a film as described above; and/or
(14) a method of making a laminated structure of one of the above types comprising the steps of: A. positioning the film and top layer with a facial surface of the top layer in facial contact with the facial surface the alkoxysilane-containing thermoplastic polyolefin copolymer facial surface of the film; and B. laminating and adhering the film to the top layer at a lamination temperature that crosslinks the alkoxysilane-containing thermoplastic polyolefin copolymer layer and provides adhering contact between the contacted facial surfaces of the film and top layer.

### DETAILED DESCRIPTION OF THE PREFERRED EMBODIMENT

Numerical ranges include all values from and including the lower and the upper values, in increments of one unit, provided that there is a separation of at least two units between any lower value and any higher value. As an example, if a compositional, physical or other property or process parameter, such as, for example, molecular weight, viscosity, melt index, temperature, etc., is from 100 to 1,000, it is intended that all individual values, such as 100, 101, 102, etc., and sub ranges, such as 100 to 144, 155 to 170, 197 to 200, etc., are expressly enumerated. For ranges containing values which are less than one or containing fractional numbers greater than one (e.g., 1.1, 1.5, etc.), one unit is considered to be 0.0001, 0.001, 0.01 or 0.1, as appropriate. For ranges containing single digit numbers less than ten (e.g., 1 to 5), one unit is typically considered to be 0.1. These are only examples of what is specifically intended, and all possible combinations of numerical values between the lowest value and the highest value enumerated, are to be considered to be expressly stated in this disclosure. Numerical ranges are provided within this disclosure for, among other things, density, melt index, amount of alkoxysilane groups in the thermoplastic polyolefin copolymer, and relative amounts of ingredients in various formulations

The term “comprising” and its derivatives inclusive terms not intended to exclude the presence of any additional component, step or procedure, whether or not the same is specifically disclosed. In order to avoid any doubt, any process or composition claimed through use of the term “comprising” may include any additional steps, equipment, additive, adjuvant, or compound whether polymeric or otherwise, unless stated to the contrary. In contrast, the term “consisting of” excludes any component, step or procedure not specifically delineated or listed. Also, the intermediate term, “consisting essentially of” excludes from the scope of any succeeding recitation any other component, step or procedure that materially affects the basic and novel characteristics of the claimed invention. The term “or”, unless stated otherwise, refers to the listed members individually as well as in any combination.

“Composition” and like terms mean a mixture of two or more materials. Included in compositions are pre-reaction, reaction and post-reaction mixtures, the latter of which will include reaction products and by-products as well as unreacted components of the reaction mixture and decomposition products, if any, formed from the one or more components of the pre-reaction or reaction mixture.

“Blend”, “polymer blend” and like terms mean a composition of two or more polymers. Such a blend may or may not be miscible. Such a blend may or may not be phase separated. Such a blend may or may not contain one or more domain configurations, as determined from transmission electron spectroscopy, light scattering, x-ray scattering, and any other method known in the art. Blends are not laminates, but one or more layers of a laminate may contain a blend.

A “polymer” or stated type of polymer means a polymeric material or resin prepared by polymerizing monomers, whether all monomers are the same type as stated or including some monomeric units of a different type. The generic term polymer thus embraces the term homopolymer, usually employed to refer to polymers prepared from only one type of monomer, and the term interpolymer or copolymer as defined below. It also embraces all forms of interpolymers, e.g., random, block, etc. The terms “ethylene/α-olefin polymer”, “propylene/α-olefin polymer” and “silane copolymer” are indicative of interpolymers as described below.

“Interpolymer” or “copolymer” may be used interchangeably and refer to a polymer prepared by the polymerization of at least two different monomers. This generic term includes copolymers prepared from two or more different monomers, e.g., terpolymers, tetrapolymers, etc.

“Catalytic amount” and like terms means an amount of catalyst sufficient to promote the rate of reaction between two or more reactants by a discernable degree.

“Cross-linking amount” and like terms means an amount of cross-linking agent or radiation or moisture or any other cross-linking compound or energy sufficient to impart at least a detectable amount of cross-linking in the composition or blend under cross-linking conditions. Cross-linking can be detected by various means depending upon the polymer type, including both direct cross-link analysis and measurement of physical changes that are indicative of a cross-linking reaction, such as decreased solubility and/or non-Newtonian melt flow behavior.

“Layer” means a single thickness, coating or stratum continuously or discontinuously spread out or covering a surface or otherwise located in a laminate structure.

“Multi-layer” means at least two layers.

“Facial surface” and like terms refer to the two major surfaces of the layers that are either an exterior or outer-facing surface of the film or are in contact with the opposite and adjacent surfaces of the adjoining layers in a laminate structure. Facial surfaces are in distinction to edge surfaces. A rectangular layer comprises two facial surfaces and four edge surfaces. A circular layer comprises two facial surfaces and one continuous edge surface.

Layers that are in “facial contact” (and like terms), means that there is contact throughout substantially the entire facial surfaces of two different adjacent layers.

Layers that are in “adhering contact” (and like terms), means that facial surfaces two different layers are in touching and binding contact to one another such that one layer cannot be removed for the other layer without damage to the in-contact facial surfaces of one or both layers.

“Photovoltaic cells” (“PV cells”) contain one or more photovoltaic effect materials of any of several known types. For example, commonly used photovoltaic effect materials include but are not limited to crystalline silicon, polycrystalline silicon, amorphous silicon, copper indium gallium (di)selenide (CIGS), copper indium selenide (CIS), cadmium telluride, gallium arsenide, dye-sensitized materials, and organic solar cell materials. The PV cells have at least one light-reactive surface that converts the incident light into electric current. Photovoltaic cells are well known to practitioners in this field and are generally packaged into photovoltaic modules that protect the cell(s) and permit their usage in their various application environments, typically in outdoor applications. As used herein, PV cells include the photovoltaic effect materials and any protective coating surface materials that are applied in their production.

“Photovoltaic modules” (“PV Modules”) contain one or more PV cells in protective enclosures or packaging that protect the cell units and permit their usage in their various application environments, typically in outdoor applications. Encapsulation films are typically used in modules disposed over and covering one or both surfaces of the PV cells.

In general, a broad range of thermoplastic polyolefin copolymers (also often generally referred to as resins, plastics and/or plastic resins) can be employed in the layers in the laminate film structures provided they can be formed into thin film or sheet layers and provide the desired physical properties. Alternative or preferred embodiments of the invention may employ one or more of the specific types of thermoplastic polyolefin copolymers and/or specific thermoplastic polyolefin copolymers in specific layers, as will be discussed further below.

The polyolefin copolymers useful in the practice of this invention are preferably polyolefin interpolymers or copolymers, more preferably ethylene/alpha-olefin interpolymers. These interpolymers have an α-olefin content needed to provide the prescribed density, generally of at least about 15, preferably at least about 20 and even more preferably at least about 25, weight percent (wt %) based on the weight of the interpolymer. These interpolymers typically have an α-olefin content of less than about 50, preferably less than about 45, more preferably less than about 40 and even more preferably less than about 35, wt % based on the weight of the interpolymer. The presence of an α-olefin and content is measured by ¹³C nuclear magnetic resonance (NMR) spectroscopy using the procedure described in Randall (Rev. Macromol. Chem. Phys., C29 (2 &3)). Generally, the greater the α-olefin contents of the interpolymer, the lower the density and the more amorphous the interpolymer.

The α-olefin is preferably a C₃₋₂₀ linear, branched or cyclic α-olefin. Examples of C₃₋₂₀α-olefins include propene, 1-butene, 4-methyl-1-pentene, 1-hexene, 1-octene, 1-decene, 1-dodecene, 1-tetradecene, 1-hexadecene, and 1-octadecene. The α-olefins can also contain a cyclic structure such as cyclohexane or cyclopentane, resulting in an α-olefin such as 3-cyclohexyl-1-propene (allyl cyclohexane) and vinyl cyclohexane. Although not α-olefins in the classical sense of the term, for purposes of this invention certain cyclic olefins, such as norbornene and related olefins, are α-olefins and can be used in place of some or all of the α-olefins described above. Similarly, styrene and its related olefins (for example, α-methylstyrene, etc.) are α-olefins for purposes of this invention. However, acrylic and methacrylic acid and their respective ionomers, and acrylates and methacrylates, and other similarly polar or polarizing unsaturated comonomers are not α-olefins for purposes of this invention. Illustrative polyolefin copolymers include ethylene/propylene, ethylene/butene, ethylene/1-hexene, ethylene/1-octene, ethylene/styrene, and the like. Ethylene/acrylic acid (EAA), ethylene/methacrylic acid (EMA), ethylene/acrylate or methacrylate, ethylene/vinyl acetate and the like copolymers similarly having polar or polarizing unsaturated comonomers are not thermoplastic polyolefin copolymers or interpolymers for purposes of the scope of this invention. Illustrative terpolymers that can be thermoplastic polyolefin copolymers or interpolymers for purposes of the scope of this invention include ethylene/propylene/1-octene, ethylene/propylene/butene, ethylene/butene/1-octene, and ethylene/butene/styrene. The copolymers can be random or block-type.

In general, relatively low density thermoplastic polyolefin copolymers are useful in the practice of this invention. In general, these are the “base” polymers that are grafted or functionalized to contain alkoxysilane or, in the case of the alkoxysilane-containing copolymers, would be polymerized containing the copolymerized alkoxysilane. Typically they would have a density of less than about 0.930 grams per cubic centimeter (g/cm³), preferably less than about 0.920, preferably less than about 0.910, preferably less than about 0.905, more preferably less than about 0.890, more preferably less than about 0.880 and more preferably less than about 0.875, grams per cubic centimeter (g/cm³). There is not, in most cases, a strict lower limit for the density of the polyolefin copolymers, but, for purposes of typical commercial processes of production, pelletizing, handling and/or processing of the resin, they will typically have a density greater than about 0.850, preferably greater than about 0.855 and more preferably greater than about 0.860, g/cm³. Density is measured by the procedure of ASTM D-792. These relatively low density polyolefin copolymers are generally characterized as semi-crystalline, flexible, resistant to water vapor transmission and having good optical properties, e.g., high transmission of visible and UV-light and low haze.

In general, the thermoplastic polyolefin copolymers useful in the practice of this invention desirably exhibit a melting point of less than about 125° C. This generally permits lamination using known and commercially available glass lamination processes and equipment. In cases of specific types of thermoplastic polyolefin copolymers useful in the practice of this invention, as discussed below, there may be preferred melting point ranges. The melting points of the thermoplastic polyolefin copolymers can be measured, as known to those skilled in the art, by differential scanning calorimetry (“DSC”), which can also be used to determine the glass transition temperatures (“Tg”) as mentioned below.

Further features of these copolymers that are also desirable include optionally, one or more of the following properties:
a 2% secant modulus of less than about 150 megaPascal (MPa) (as measured by ASTM D-790, and
a glass transition temperature (Tg) of less than about −35° C. as measured by DSC.

The polyolefin copolymers useful in the practice of this invention typically have a melt index of greater than or equal to about 0.10, preferably greater than or equal to about 1 gram per 10 minutes (g/10 min) and less than or equal to about 75 and preferably of less than or equal to about 10 g/10 min. Melt index is measured by the procedure of ASTM D-1238 (190° C./2.16 kg).

More specific examples of the polyolefin copolymers useful in this invention prior to or excluding the alkoxysilane incorporation include very low density polyethylene (VLDPE) (e.g., FLEXOMER® ethylene/1-hexene polyethylene made by The Dow Chemical Company), homogeneously branched, linear ethylene/alpha-olefin copolymers (e.g. TAFMER® by Mitsui Petrochemicals Company Limited and EXACT® by Exxon Chemical Company), homogeneously branched, substantially linear ethylene/alpha-olefin polymers (e.g., AFFINITY® and ENGAGE® polyethylene available from The Dow Chemical Company), and olefin block copolymers (OBC's) such as those described in U.S. Pat. No. 7,355,089 (e.g., INFUSE® available from The Dow Chemical Company). Specific preferred types of polyolefin copolymers include olefin block-type copolymers (OBC) and homogeneously branched, substantially linear ethylene copolymers (SLEP).

Regarding the preferred homogeneously branched substantially linear ethylene copolymers (SLEP's), these are examples of “random polyolefin copolymers” and the description of these types of polymers and their use in PV encapsulation films is discussed in 2008/036708 and they are more fully described in U.S. Pat. Nos. 5,272,236, 5,278,272 and 5,986,028, all of which are incorporated herein by reference. As is known, the SLEP-types of polyolefin copolymers are preferably made with a single site catalyst such as a metallocene catalyst or constrained geometry catalyst. These polyolefin copolymer typically have a melting point of less than about 95° C., preferably less than about 90° C., more preferably less than about 85° C., even more preferably less than about 80° C. and still more preferably less than about 75° C.

Similarly preferred are the olefin block copolymer (OBC) types of polyolefin copolymers, which are examples of “block-type polyolefin copolymers” and are typically made with chain shuttling-types of catalysts. The description of these types of polymers in their use in PV encapsulation films is discussed in 2008/036707, incorporated herein by reference. These block-types of polyolefin copolymers typically have a melting point of less than about 125° C. and preferably from about 95° C. to about 125° C.

For other types of polyolefin copolymers made with multi-site catalysts, e.g., Ziegler-Natta and Phillips catalysts, the melting point is typically from about 115 to 135° C. The melting point is measured by differential scanning calorimetry (DSC) as described, for example, in U.S. Pat. No. 5,783,638. Polyolefin copolymers with a lower melting point often exhibit desirable flexibility and thermoplasticity properties useful in the fabrication of the modules of this invention. Similarly suitable is an ethylene-based block-type polymer as described in U.S. Pat. No. 5,798,420 and having an A block and a B block, and if a diene is present in the A block, a nodular polymer formed by coupling two or more block polymers.

Blends of any of the above thermoplastic polyolefin copolymer resins can also be used in this invention and, in particular, the thermoplastic polyolefin copolymers can be blended or diluted with one or more other polymers to the extent that the polymers are (i) miscible with one another, (ii) the other polymers have little, if any, impact on the desirable properties of the polyolefin copolymer, e.g., optics and low modulus, and (iii) the thermoplastic polyolefin copolymers of this invention constitute at least about 70, preferably at least about 75 and more preferably at least about 80 weight percent of the blend. Preferably the blend itself also possesses the density, melt index and melting point properties noted above.

The alkoxysilane-containing thermoplastic polyolefin copolymers used for the films of this invention require, of course, alkoxysilane groups that are grafted or otherwise bonded into the thermoplastic polyolefin copolymer. Alkoxysilane groups can be incorporated into the thermoplastic polyolefin copolymer as generally described above using known monomeric reactants in a polymerization process, known grafting techniques, or other functionalization techniques. Any alkoxysilane group-containing compound or monomer that will effectively improve the adhesion (especially glass adhesion) of the thermoplastic polyolefin copolymer and can be grafted/incorporated therein and subsequently crosslinked, can be used in the practice of this invention.

Grafting of a graftable alkoxysilane compound to a suitable polyolefin copolymer has been found to be very well suited for obtaining the desired combination of polyolefin copolymer properties and alkoxysilane content. Suitable alkoxysilanes for alkoxysilane grafting and the cross-linking process include alkoxysilanes having an ethylenically unsaturated hydrocarbyl group and a hydrolyzable group, particularly the alkoxysilanes of the type which are taught in U.S. Pat. No. 5,824,718. It should be understood that as used herein:
the term “alkoxysilane” as grafted or in a graftable compound, refers to bonded alkoxysilane groups represented by the following formula:

—CH₂—CHR₁—(R²)ₘ—Si(R³)₃₋ₙ(OR⁴)ₙ I

and, the term “graftable alkoxysilane compound” and referring to “alkoxysilane” compounds before grafting refers to alkoxysilane compounds that can be described by the following formula:

CH₂═CR¹—(R²)ₘ—Si(R³)₃₋ₙ(OR⁴)ₙ II,

where, in either case I or II:
R¹ is H or CH₃;
R² is alkyl, aryl, or hydrocarbyl containing from 1 to 20 carbon atoms and may also include other functional groups, such as esters, amides, and ethers, among others;
m is 0 or 1;
R³ is alkyl, aryl, or hydrocarbyl containing from 1 to 20 carbon atoms;
R⁴ is alkyl or carboxyalkyl containing from 1 to 6 carbon atoms (preferably methyl or ethyl);
n is 1, 2, or 3 (preferably 3).

Suitable alkoxysilane compounds for grafting include unsaturated alkoxysilanes where the ethylenically unsaturated hydrocarbyl groups in the general formula above, can be a vinyl, allyl, isopropenyl, butenyl, cyclohexenyl, or (meth)acryloxyalkyl (refers to acryloxyalkyl and/or methacryloxyalkyl) group, the hydrolyzable group, denoted as OR⁴ in the general formula, can be methoxy, ethoxy, propoxy, butoxy, formyloxy, acetoxy, proprionyloxy, and alkyl- or arylamino groups and the saturated hydrocarbyl group, denoted as R³ in the general formula, if present can be methyl or ethyl. These alkoxysilanes and their method of preparation are more fully described in U.S. Pat. No. 5,266,627. Preferred alkoxysilane compounds include vinyltrimethoxysilane (VTMOS), vinyltriethoxysilane (VTEOS), allyltrimethoxysilane, allyltriethoxysilane, 3-acryloylpropyltrimethoxysilane, 3-acryloylpropyltriethoxysilane, 3-methacryloylpropyltrimethoxysilane, and 3-methacryloylpropyltriethoxysilane and mixtures of these silanes.

The amount of alkoxysilane needed in copolymers and films for the practice of this invention, can vary depending upon the nature of the thermoplastic polyolefin copolymer, the alkoxysilane, the processing conditions, the grafting efficiency, the amount and type of adhesion required in the ultimate application, and similar factors. The outcome desired from incorporating sufficient amounts of alkoxysilane groups is to provide sufficient adhesion prior to cross-linking and, following crosslinking, to provide necessary copolymer physical properties. In the case where glass adhesion is desired, the grafted silane level needs to be sufficient in the thermoplastic polyolefin copolymer film surface contacting a glass layer to have adequate adhesion to glass for the given application. For example, some applications, such as some of the photovoltaic cell laminate structures, can require an adhesive strength to glass of at least about 5 Newtons per millimeter (“N/mm”) as measured by the 180 degree peel test. The 180-degree peel test is generally known to practitioners. Other applications or structures may require lower adhesive strength and correspondingly lower silane levels.

For the desired thermoplastic polyolefin copolymer film physical properties after cross-linking, it is typically necessary to obtain a gel content in the thermoplastic polyolefin resin, as measured by ASTM D-2765, of at least 30, preferably at least 40, preferably at least 50 and more preferably at least 60 and even more preferably at least 70, percent. Typically, the gel content does not exceed 90 percent.

With the adhesion and cross-linking goals in mind, there is preferably at least 0.1 percent by weight alkoxysilane in the grafted polymer, more preferably at least about 0.5% by weight, more preferably at least about 0.75% by weight, more preferably at least about 1% by weight, and most preferably at least about 1.2% by weight. Considerations of convenience and economy are usually the two principal limitations on the maximum amount of grafted alkoxysilane used in the practice of this invention. Typically, the alkoxysilane or a combination of alkoxysilanes, is added in an amount such that the alkoxysilane level in the grafted polymer is 10 percent by weight or less, more preferably less than or equal to about 5% by weight, more preferably less than or equal to about 2% by weight in the grafted polymer. The level of alkoxysilane in the grafted polymer can be determined by first removing the unreacted alkoxysilane from the polymer and then subjecting the resin to neutron activation analysis of silicon. The result, in weight percent silicon, can be converted to weight percent grafted alkoxysilane.

As mentioned above, grafting of the alkoxysilane to the thermoplastic polyolefin polymer can be done by many known suitable methods, such as reactive extrusion or other conventional method. The amount of the graftable alkoxysilane compound needed to be employed in the grafting reaction obviously depends upon the efficiency of the grafting reaction and the desired level of grafted alkoxysilane to be provided by the grafting reaction. The amount needed to be employed can be calculated and optimized by simple experimentation and knowing that the grafting reaction typically has an efficiency of about 60%. Thus, obtaining the desired level of grafted alkoxysilane usually requires incorporation of an excess of about 40%.

Graft initiation and promoting techniques are also generally well known and include by the known free radical graft initiators such as, for example, peroxides and azo compounds, or by ionizing radiation, etc. Organic free radical graft initiators are preferred, such as any one of the peroxide graft initiators, for example, dicumyl peroxide, di-tert-butyl peroxide, t-butyl perbenzoate, benzoyl peroxide, cumene hydroperoxide, t-butyl peroctoate, methyl ethyl ketone peroxide, 2,5-dimethyl-2,5-di(t-butyl peroxy)hexane, lauryl peroxide, and tert-butyl peracetate. A suitable azo compound is azobisisobutyl nitrile. While any conventional method can be used to graft the alkoxysilane groups to the thermoplastic polyolefin polymer, one preferred method is blending the two with the graft initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

In those embodiments of films comprising two or more layers of alkoxysilane-containing thermoplastic polyolefin, the amount of alkoxysilane in each layer can be the same or different, and each layer can contain the same or different alkoxysilane, e.g., in one layer the thermoplastic polyolefin can be grafted with vinyltrimethoxysilane while the other layer the same or different thermoplastic polyolefin is grafted with vinyltriethoxysilane, or in one layer the thermoplastic polyolefin is grafted with vinyltrimethoxysilane while the other layer comprises poly(ethylene-co-vinyltrimethoxysilane) copolymer. In one embodiment, the amount of alkoxysilane in one layer may be at least twice, thrice or four-times as much as the alkoxysilane in the other layer, or at least one of the other layers.

### Catalyst for Crosslinking the Alkoxysilane Groups

As mentioned above, the various film laminate structure and laminating process embodiments of the present invention employ a specific crosslinking catalyst that, under the desired specific conditions discussed below, catalyzes or accelerates the alkoxysilane cross-linking (also referred to as “curing”). These are also known as and sometimes referred to herein as “catalyst”. The crosslinking catalyst is a Lewis or Bronsted acid or base compound, which types of compounds are known to catalyze the crosslinking. Many such materials are known to those familiar with the art, including, without limitation, aromatic sulfonic acids, organic tin compounds, organic titanium compounds, organic zinc compounds, and organic zirconium compounds. However, unlike the known catalysts typically used, the catalyst used according to the present invention is required to be a solid at room temperature and have a melting point temperature in a specific range that is greater than the typical maximum ambient temperature of copolymer handling, transportation, and storage. The maximum ambient temperatures for handling, transportation, and storage of the thermoplastic polyolefin copolymers and films that are prepared according to the present invention are typically up to about 45° C., sometimes up to about 50° C., occasionally up to about 55° C., and in some situations can be as high as about 60° C., these temperatures obviously depending upon the geographic location and season. Thus, correspondingly, the melting point temperatures for the cross-linking catalysts used according to the present invention are typically greater than or equal to about 50° C., desirably greater than or equal to about 55° C., preferably greater than or equal to about 70° C. and most preferably, to ensure maximum copolymer and film stability, greater than or equal to about 80° C.

The upper limit for the cross-linking catalysts' melting point is established by the need for the catalysts to be able to melt and to be mobile enough to diffuse in the thermoplastic polyolefin copolymer at or near the lamination temperature. Thus, the cross-linking catalysts preferably have a melting point temperature (i.e., melt and are in a liquid form) that is less than or equal to about the temperature at which the film comprising the catalyst and alkoxysilane are laminated with glass and other optional layers to provide laminated structures. The thermoplastic polyolefin copolymers are typically laminated by heating to a temperature at or above the melting point of the thermoplastic polyolefin, preferably at about 20° C. or more above the melting point of the copolymer. Therefore, relative to the copolymer melting point, a crosslinking catalyst for use according to the present invention should have a melting point at or below the laminating temperature of the copolymer, which laminating temperature is typically about 20° C. or more above the copolymer melting point. In very general terms, for the lamination of some typical glass and thermoplastic film layers on commercial lamination equipment, and depending upon adjustments that may be needed for specific combinations of layers, at the lower end, the lamination temperatures need to be at least about 130° C., preferably at least about 140° C. and, at the upper end, less than or equal to about 170° C., preferably less than or equal to about 160° C. Preferably, effective crosslinking catalysis only occurs at lamination temperature conditions and not at lower temperatures.

As used herein, the “melting point temperatures” are determined by ASTM D7426-08 for the catalysts compounds and for the thermoplastic polyolefin copolymers.

Compositionally, suitable cross-linking catalysts include such compounds having a melting point temperature within the specified ranges and having a chemical structure represented by one or more of the following formulae:

(a) R—SO₃H,

(b) R₂Sn^{IV}(OZ)₂,

(c) [R₂Sn^{IV}(OZ)]₂O,

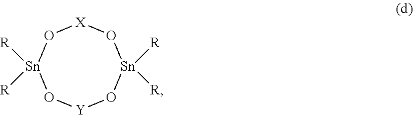

(e) R¹R²R³R⁴Ti^{IV}, or

(f) R¹R²R³R⁴Zr^{IV};

where each R is independently a monovalent hydrocarbon group with from 1 to 24 carbon atoms, each R¹, R², R³, and R⁴ are independently selected from monovalent alkoxy, aryloxyl, or carboxyl groups with from 1 to 24 carbon atoms, X and Y are independently selected from divalent alkoxy, aryloxyl, or carboxyl groups with from 1 to 6 carbon atoms, and Z is an organic group with from 1 to 24 carbon atoms having a functional group that can form a coordinate bond with Sn. It has been found to be preferred to use a crosslinking catalyst as represented by formulae (b) or (c), above. In particular, suitable cross-linking catalysts include one or more compound selected from the group consisting of: 1,3-diacetoxy-1,1,3,3-tetrabutyldistannoxane and dibutyltin maleate.

The following are examples of catalysts suitable for use according to the present invention or, in the first case, a comparative liquid catalyst used below in the Experiments.

Dibutyltin Dilaurate;

(C₄H₉)₂Sn(OOC(CH₂)₁₀CH₃)₂/C₃₂H₆₄O₄Sn

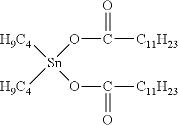

This compound has a listed melting point of 22-24° C. and is available from Aldrich. For purposes of this application, this is a comparative example liquid catalyst.

### 1,3-Diacetoxy-1,1,3,3-tetrabutyldistannoxane

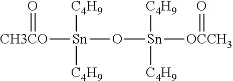

This compound is commercially available from Aldrich and has a listed melting point of 56-58 C.

Dibutyltin Maleate

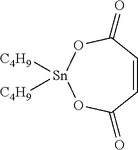

This compound is commercially available and can be purchased from Aldrich. The material safety data sheet for this compound from Aldrich lists its melting point as 135-140 C.

The crosslinking catalyst used in the practice of this invention is used in the thermoplastic polyolefin copolymers at levels sufficient to catalyze the alkoxysilane crosslinking reaction and provide desired levels of tensile strength, shear strength and creep resistance in a film product and laminated structure. Suitable concentrations depend upon a number of factors including:
whether the compound is dispersed in the alkoxysilane-containing copolymer or, in the case of a layered film, in an adjacent layer; with usage in the adjacent layer generally requiring somewhat higher concentrations;
The degree of cross-linking needed for sufficient physical properties in the thermoplastic polyolefin copolymer;
The time in which substantially complete crosslinking is needed (higher concentrations are needed to have the copolymer substantially crosslinked more quickly after the lamination step).

Thus, when employed in or preferably adjacent to the alkoxysilane-containing thermoplastic polyolefin copolymer, it has been found suitable to employ concentrations of at least about 0.0005 weight percent (50 ppm), desirably at least about 0.0007 weight percent and preferably at least about 0.001 weight percent; said weight percent being determined based upon weight of the thermoplastic polyolefin copolymer in which the cross-linking catalyst is dispersed.

The maximum concentrations of the alkoxysilane cross-linking catalyst are generally determined based upon cost and upon avoidance of undesired excessive cross-linking rates (cross-linking prematurely) and cross-linking levels (gel) that would otherwise affect the desirable optical and processing properties of the copolymer and films. Therefore, the cross-linking catalysts are generally employed in the thermoplastic copolymers and films according to the present invention at concentrations of less than about 1 weight percent (10,000 ppm), desirably less than about 0.5 weight percent, preferably less than about 0.25 weight percent, more preferably less than about 0.1 weight percent, more preferably less than about 0.05 weight percent and more preferably less than about 0.01 weight percent. It has been found generally acceptable to employ the cross-linking catalysts compounds mentioned above at levels of from about 0.001 weight percent to about 0.1 weight percent.

The cross-linking catalyst obviously must be sufficiently resistant to melting and decomposition under the conditions used to disperse it in the copolymer, construct film structures that will be used to prepare laminated structures and the subsequent handling shipping and storage of the films prior to their use in a lamination step. Then, during and after lamination at elevated temperatures the catalyst will melt and diffuse sufficiently through the thermoplastic polyolefin copolymer to contact and initiate cross-linking of the alkoxysilane groups in the thermoplastic polyolefin copolymer. Preferably, the films do not significantly crosslink (to a degree detrimental to adhesion) prior to lamination and preferably effective cross-linking catalysis occurs primarily at or after adhesion to adjacent layer(s) and at glass lamination temperature conditions (and not at lower temperatures). Preferably, the catalyst will not interfere with or significantly deteriorate the film adhesion during preparation of the laminate or the performance of the laminated structure, e.g., a photovoltaic cell, during the useful life of the structure. In this way, according to the present invention, the catalyst does not interfere with or deteriorate the adhesion of the thermoplastic polyolefin copolymer to other layers such as glass.

The thermoplastic polyolefin copolymer films comprising alkoxysilane groups and the specified cross-linking catalyst can be prepared according to processes and techniques that are generally known and using equipment and technology that are commercially available and suitable for preparation of the desired products having the cross-linking catalyst homogeneously distributed throughout a thermoplastic polyolefin copolymer. In one embodiment, the specified catalyst may be distributed in the thermoplastic polyolefin copolymer lamination film layer comprising the alkoxysilane groups. The relatively higher catalyst melting point delays cross-linking until after the film has sufficient adhesion.

Alternatively, in the case of layered or laminate structure thermoplastic polyolefin copolymer lamination films (and where cross-linking is desirably avoided in at least one film surface during its lamination to a glass or other layer), the catalyst is located in one or more separate layers that is/are adjacent to alkoxysilane-containing thermoplastic polyolefin copolymer layer(s). In such cases, the catalyst-containing layer(s), may or may not contain alkoxysilane and would not be utilized for adhesion to glass or other similar layer. In certain embodiments of the lamination films according to the invention, a glass-contacting facial surface layer comprises alkoxysilane groups and essentially no cros-slinking catalyst while the specified cross-linking catalyst is located in a separate layer (with or without alkoxysilane groups) directly adjacent to and in adhering facial contact with the alkoxysilane-containing layer. In a preferred variant of the embodiment, preferably the same thermoplastic polyolefin copolymer is employed for separate catalyst-containing thermoplastic polyolefin copolymer layers and alkoxysilane-containing thermoplastic polyolefin copolymer layers. Preferably, a catalyst-containing layer that is separate from the alkoxysilane-containing layer does not contain alkoxysilane groups.

Layered films having separate catalyst- and alkoxysilane-containing layers can be prepared by known coextrusion or film lamination techniques, preferably adding the catalyst to the polymer melt in the extruder supplying the feed stream for that layer. If the catalyst-containing layer does not contain any alkoxysilane (and therefore does not crosslink), that film layer is prepared sufficiently thin, e.g., between 0.05 and 2, preferably between 0.1 and 1 and more preferably between 0.15 and 0.3, millimeters (mm), such that it will not deleteriously affect the mechanical strength of the film or laminated structure at elevated temperatures.

In one embodiment of the present invention, the films have at least two thermoplastic polyolefin copolymer layers including at least one thermoplastic polyolefin copolymer surface layer comprising the alkoxysilane groups. Then, regarding the cross-linking catalyst, there are several options including:

(i) the layer or layers comprising the alkoxysilane groups, including surface layer(s), comprise the cross-linking catalyst; or

(ii) the layer or layers comprising alkoxysilane groups do not contain cross-linking catalyst but have a facial surface in adhering contact with a layer of a thermoplastic polyolefin copolymer comprising the cross-linking catalyst; or

(iii) a combination of layers (i) and (ii).

In one variation of this embodiment, the film comprises two alkoxysilane-containing surface layers according to (ii) above which do not contain cross-linking catalyst, at least one interior layer comprising cross-linking catalyst and each surface layer has an interior facial surface in adhering contact with a facial surface of a catalyst-containing layer.

The layered or laminate films according to the present invention can advantageously employ known techniques of providing multiple layers and providing nearly any number of layers up to and including the structures known in the art containing large numbers of layers and often referred to as “microlayer” structures. There are many known techniques which can be employed for multilayer films (up to and including microlayer films), including for example in U.S. Pat. No. 5,094,788; U.S. Pat. No. 5,094,793; WO/2010/096608; WO 2008/008875; U.S. Pat. No. 3,565,985; U.S. Pat. No. 3,557,265; U.S. Pat. No. 3,884,606; U.S. Pat. No. 4,842,791 and U.S. Pat. No. 6,685,872 all of which are hereby incorporated by reference herein. As will be apparent to practitioners in the area of film production, these and other techniques can be employed to provide structures wherein the cross-linking catalyst and alkoxysilane groups are in separate, optionally alternating layers that have facial surfaces in adhering contact. Included are a broad range of films including films comprising at least about 3 layers, at least about 5 layers, at least about 10 layers, at least about 25 and at least about 30 layers. Also, although the number of layers in the streams may be essentially limitless, the streams may be optimized to contain up to and including about 10,000 layers, 1,000 or less layers, 500 or less layers, about 200 or less layers, and about 100 or less layers.

### Other Additives

The polymeric materials of this invention can comprise additives other than or in addition to the alkoxysilane cross-linking catalyst. For example, such other additives include UV absorbers, UV-stabilizers and processing stabilizers such as trivalent phosphorus compounds. The selection of UV absorbers, if any, should coordinate with the intended application, such as PV modules where the absorption should not significantly reduce the photovoltaic performance. Such UV absorbers can include, for example, benzophenones derivatives such as Cyasorb UV-531, benzotriazoles such as Cyasorb UV-5411, and triazines such as Cyasorb UV-1164. The UV-stabilizers include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus-containing stabilizer compounds include phosphonites (PEPQ) and phosphites (Weston 399, TNPP, P-168 and Doverphos 9228). The amount of UV-stabilizer is typically from about 0.1 to 0.8%, and preferably from about 0.2 to 0.5%. The amount of processing stabilizer is typically from about 0.02 to 0.5%, and preferably from about 0.05 to 0.15%.

Still other additives include, but are not limited to, antioxidants (e.g., hindered phenolics such as Irganox® 1010 made by Ciba Geigy Corp.), cling additives (e.g., polyisobutylene), anti-blocks, anti-slips, pigments and fillers (clear if transparency is important to the application). In-process additives, e.g. calcium stearate, water, etc., may also be used. These and other potential additives are used in the manner and amount as is commonly known in the art.

### Glass

When used in certain embodiments of the present invention, “glass” refers to a hard, brittle, transparent solid, such as that used for windows, many bottles, or eyewear, including, but not limited to, soda-lime glass, borosilicate glass, sugar glass, isinglass (Muscovy-glass), or aluminum oxynitride. In the technical sense, glass is an inorganic product of fusion which has been cooled to a rigid condition without crystallizing. Many glasses contain silica as their main component and glass former.

Pure silicon dioxide (SiO₂) glass (the same chemical compound as quartz, or, in its polycrystalline form, sand) does not absorb UV light and is used for applications that require transparency in this region. Large natural single crystals of quartz are pure silicon dioxide, and upon crushing are used for high quality specialty glasses. Synthetic amorphous silica, an almost 100% pure form of quartz, is the raw material for the most expensive specialty glasses.

The glass layer of the laminated structure is typically one of, without limitation, window glass, plate glass, silicate glass, sheet glass, float glass, colored glass, specialty glass which may, for example, include ingredients to control solar heating, glass coated with sputtered metals such as silver, glass coated with antimony tin oxide and/or indium tin oxide, E-glass, and Solexia™ glass (available from PPG Industries of Pittsburgh, Pa.).

Alternatively to glass or in addition to glass, other known materials can be employed for one or more of the layers with which the lamination films according to the present invention are employed. These layers, sometimes referred to in various types of structures as “cover”, “protective”, “top” and/or “back” layers, can be one or more of the known rigid or flexible sheet materials, including for example, materials such as polycarbonate, acrylic polymers, a polyacrylate, a cyclic polyolefin such as ethylene norbornene, metallocene-catalyzed polystyrene, polyethylene terephthalate, polyethylene naphthalate, fluoropolymers such as ETFE (ethylene-tetrafluoroethlene), PVF (polyvinyl Fluoride), FEP (fluoroethylene-propylene), ECTFE (ethylene-chlorotrifluoroethylene), PVDF (polyvinylidene fluoride), and many other types of plastic, polymeric or metal materials, including laminates, mixtures or alloys of two or more of these materials. The location of particular layers and need for light transmission and/or other specific physical properties would determine the specific material selections.

### Laminated Structures

The laminated structures according to the present invention employ the thermoplastic polyolefin copolymer lamination films and at least one additional layer, such as glass or one of the sheet materials described above. Preferred types of laminated structures include PV modules, safety glass or insulated glass. For example, a method for the preparation of these structures (as exemplified in an embodiment where a glass layer is employed) comprises the steps of:

A. positioning the film and glass (or other layer) with a facial surface of the glass layer in facial contact with the facial surface the alkoxysilane-containing thermoplastic polyolefin copolymer facial surface of the film;

B. laminating and adhering the film to the glass layer at a lamination temperature that cross-links the alkoxysilane-containing thermoplastic polyolefin copolymer layer and provides adhering contact between the contacted facial surfaces of the film and glass.

The laminated structures of this invention are structures comprising (i) a glass or other layer, (ii) a first alkoxysilane-containing polyolefin (thermoplastic polyolefin) layer, (iii) a catalyst layer, and (iv) a second alkoxysilane-containing polyolefin layer. In the lamination process to construct a laminated structure, a facial surface of thermoplastic polyolefin copolymer that contains alkoxysilane groups is put into adhering contact with a facial surface of the glass or other layer. These structures can be constructed by any one of a number of different methods. For example, in one method the structure is simply built layer upon layer, e.g., the first alkoxysilane-containing polyolefin layer is applied in any suitable manner to the glass or other layer, followed by the application of the catalyst layer (if catalyst is to be kept separate from the alkoxysilane of the first layer) to the first alkoxysilane-containing polyolefin layer, followed by the application, if applicable, of the second alkoxysilane-containing polyolefin layer to the catalyst layer. The application of the catalyst layer to the first alkoxysilane-containing polyolefin and the application of the second alkoxysilane-containing polyolefin to the catalyst layer can be by any process known in the art, e.g., extrusion, calendering, solution casting or injection molding. In another method, alkoxysilane-containing and cross-linking-catalyst containing thermoplastic polyolefin layers are simultaneously coextruded and formed into a multi-layer structure which is then applied to the glass layer, optionally encapsulating a PV cell.

The copolymers and particularly the films of the present invention can be used to construct electronic device modules, e.g., photovoltaic or solar cells, in the same manner and using the same amounts as the encapsulant materials known in the art, e.g., such as those taught in U.S. Pat. No. 6,586,271, US Patent Application Publication US2001/0045229 A1, WO 99/05206 and WO 99/04971. These materials can be used as “skins” for the electronic device, i.e., applied to one or both face surfaces of the device, or as an encapsulant in which the device is totally enclosed within the material. As mentioned above, the polymeric materials can be applied to the device by the layer upon layer technique or, alternatively, a multi-layer laminated structure comprising separate alkoxysilane-containing and catalyst layers can first be prepared and then applied to facial surfaces of the device either sequentially or simultaneously followed by the application of a glass or other protective layer to one or both surfaces of the multi-layer laminated film structures now in adhering contact with the electronic device.

In another embodiment, the polymeric materials used in the practice of this invention can be used to construct “safety glass” in the same manner as that known in the art. In this application, typically a multi-layer laminated structure comprising the catalyst layer sandwiched between alkoxysilane-containing thermoplastic polyolefin layers is first prepared and laminated to one sheet of glass or other rigid transparent sheet material. This is followed by laminating a second sheet of glass or other rigid transparent sheet material to the open facial surface of the multi-layer laminated structure, i.e., the polymeric film. Alternatively, the polymeric film can be built layer by layer upon one of the facial surfaces of the first glass layer.

In general, the laminated PV structures of this invention are structures comprising in sequence, starting with the top sheet, the layer upon which the light intended to be received initially contacts: (i) a light-receiving top sheet layer, (ii) a alkoxysilane-containing thermoplastic polyolefin copolymer encapsulating film layer according to the present invention (optionally containing other internal layers or components not adversely or detrimentally affecting adhesion and light transmission), (iii) a photovoltaic cell, (iv) if needed, a second alkoxysilane-containing thermoplastic polyolefin copolymer encapsulating film layer (optionally according to the present invention) and, (v) if needed, a back sheet or layer comprising glass or other back layer substrate.

In any case, in the lamination process to construct a laminated PV module, at least the following layers are brought into facial contact:
a light-receiving top sheet layer (e.g., a glass layer) having an “exterior” light-receiving facial surface and an “interior” facial surface;
an alkoxysilane-containing thermoplastic polyolefin copolymer film having one facial surface directed toward the glass and one directed toward the light-reactive surface of the PV cell and encapsulating the cell surface;
a PV cell;
if needed, a second encapsulating film layer (optionally according to the present invention); and
a back layer comprising glass or other back layer substrate.

With the layers or layer sub-assemblies assembled in desired locations the assembly process typically requires a lamination step with heating and compressing at conditions sufficient to create the needed adhesion between the layers. In general, lamination temperatures will depend upon the specific thermoplastic polyolefin copolymer layer materials being employed and the temperatures necessary to achieve their adhesion. In general, at the lower end, the lamination temperatures need to be at least about 130° C., preferably at least about 140° C. and, at the upper end, less than or equal to about 170° C., preferably less than or equal to about 160° C.

In ways like this, these films can be used as “skins” for the photovoltaic cells in photovoltaic modules, i.e., applied to one or both face surfaces of the cell as an encapsulant in which the device is totally enclosed within the films. The structures can be constructed by any one of a number of different methods. For example, in one method the structure is simply built layer upon layer, e.g., the first alkoxysilane-containing polyolefin encapsulating film layer is applied in any suitable manner to the glass, followed by the application of the photovoltaic cell, second encapsulating film layer and back layer.

In one embodiment, the photovoltaic module comprises (i) at least one photovoltaic cell, typically a plurality of such devices arrayed in a linear or planar pattern, (ii) at least one cover sheet or protective layer on the surface intended for light to contact, (typically a glass or other cover sheet over both face surfaces of the device), and (iii) at least one encapsulation film layer according to the present invention. The encapsulation film layer(s) are typically disposed between the cover sheet(s) and the cells and exhibit good adhesion to both the device and the cover sheet, low shrinkage, and good transparency for solar radiation, e.g., transmission rates in excess of at least about 85, preferably at least about 90, preferably in excess of 95 and even more preferably in excess of 97, percent as measured by UV-vis spectroscopy (measuring absorbance in the wavelength range of about 280-1200 nanometers. An alternative measure of transparency is the internal haze method of ASTM D-1003-00. If transparency is not a requirement for operation of the electronic device, then the polymeric material can contain opaque filler and/or pigment.

The following examples further illustrate the invention. Unless otherwise indicated, all parts and percentages are by weight.

### Specific Embodiments

Comparative Films 1-5 Two types of 3-layer films were prepared by lamination at 150° C. to compare a lower melting point liquid phase crosslink catalyst and no catalyst. Films with the structure A-B-A and A-C-A were prepared by laminating together the following layers to produce films having a total thickness of about 18 mils. The analysis data for these films is shown in Table 1 below:

Component Layer A: A layer composed of a polyolefin copolymer blend that contained about 1.2 weight percent grafted trialkoxysilane groups. Neutron activation analysis was used to determine the level of grafted alkoxysilane in the products. The blend components are:

ENGAGE™ 8200 brand thermoplastic polyolefin copolymer

Density—0.870 grams per cubic centimeter (g/cc) as measured by ASTM D792.

Melt Index—5 g/10 min as measured by ASTM D-1238 (190° C./2.16 kg).

Melting point—59° C. as measured by differential scanning calorimetry,

2% secant modulus—1570 psi (10.8 MPa) as measured by ASTM D-790,

α-olefin—1-octene

Tg of −63.4° F. (−53° C.) as measured by differential scanning calorimetry.

ENGAGE™ 8440 brand thermoplastic polyolefin copolymer

Density—0.897 g/cc as measured by ASTM D792.

Melt Index—1.6 g/10 min ASTM D-1238 (190° C./2.16 kg).

Melting point—93° C. as measured by differential scanning calorimetry.

2% secant modulus—7880 psi (54.3 MPa) as measured by ASTM D-790,

α-olefin—1-octene

Tg of −27.4° F. (−33° C.) as measured by differential scanning calorimetry.

Formulation of the Component Layer A (alkoxysilane-containing, no cross-linking catalyst)

ENGAGE 8200™ 70.65

ENGAGE 8440™ 27.48

Dow Corning Z-6300 silane (VTMS) 1.78

Luperox 101 0.089

Component Layer B: A layer composed of a polyolefin copolymer (containing no alkoxysilane) and containing dibutyltin dilaurate (DBTDL, 1000 ppm) liquid cross-linking catalyst. The thickness of this layer was 18 mils, 9 mils, or 4 mils, as described below. The polyolefin copolymer component of the layer was:

ENGAGE™ EG 8100 brand thermoplastic polyolefin copolymer

Density—0.87 g/cc as measured by ASTM D792.

Melt Index—1 g/10 min ASTM D-1238 (190° C./2.16 kg).

Melting point—60° C. as measured by differential scanning calorimetry.

2% secant modulus—1901 psi (13.1 MPa) as measured by ASTM D-790,

α-olefin—1-octene

Tg of −61.6° F. (−52° C.) as measured by differential scanning calorimetry.

Component C: A film identical to Component B except that it contained no DBTDL. This layer was either 18 mils thick or 9 mils thick.

The 3-layer films were laminated by a laminator with the following conditions: 5 minutes vacuum at 150 C, 10 minutes with full pressure at 150 C. The films identified as Films 1 through 5 below have the indicated structures where, where the center component B or C had the indicated thickness of 18 mils, 9 mils, or 4 mils. The concentrations of DBTDL in the layers B and C are 1000 ppm and 0 ppm, respectively. The total concentrations in the 3-layer films are shown Table 1 below. The films were exposed to ambient conditions (approximately 22° C., 50% RH) and samples of each film were withdrawn after the indicated times: 2 days, 1 week, 2 weeks and 3 weeks. The samples were tested for gel content to determine the extent of cross-linking that had occurred during the exposure conditions.

Gel content was determined by extraction with boiling xylene. In this procedure, samples consisting of 0.1-0.5 g of the film to be tested were weighed and placed in a basket made of metal mesh. The basket containing the sample was sealed and weighed. It was placed in the extraction chamber of a Soxhlet extractor, and it was extracted with boiling xylene overnight, at least 16 hours. The basket and extracted sample were removed from the extractor, dried for at least 2 h in a vacuum oven at 160° C., and weighed. The weight of the insoluble portion of the film was assumed to be cross-linked gel. The table below lists the results of this analysis. The weight percentage gel fractions that are reported are based only on the “A” portion of the 3-layer films, since the “B” and “C” portions did not have alkoxysilane groups, and therefore would not contribute to the cross-linked material.

The results indicate that the liquid catalyst in the “B” layer diffused into the “A” layer readily and cross-linking occurred within several days at ambient conditions. On the other hand, the samples without catalyst underwent essentially no cross-linking at ambient conditions even after 3 weeks, and significantly elevated temperatures were required before substantial levels of gel were observed. This demonstrates that with a liquid catalyst, cross-linking occurs uncontrolled at ambient conditions; with no catalyst, cross-linking occurs very slowly at ambient conditions.

TABLE 1
Gel Fraction Data for Liquid Cross-linking Catalyst in 3-layer Films

| | | | Gel Fraction after Indicated | | | |
|---|---|---|---|---|---|---|
| | | | Times Under Ambient | | | |
| Film | | Catalyst | Conditions | | | |
| No. | Layer structure | conc | 2 days | 1 wk | 2 wk | 3 wk |
| 1 | A-B18-A | 333 ppm | 78% | 84% | 81% | — |
| 2 | A-B9-A | 200 ppm | 58% | 76% | 75% | — |
| 3 | A-B4-A | 100 ppm | 61% | 66% | 63% | — |
| 4 | A-C18-A | 0 | 0% | 0% | 1% | 1% |
| 5 | A-C9-A | 0 | 0% | 0% | 5% | 0% |

Comparative Films 6 and 7: The films described below containing liquid cross-linking catalyst were laminated to glass. The following monolayer films were used to measure glass adhesion:

Component A Film: Composition as described above. The thickness of this film was about 18 mils

Component D Film: A film was prepared from the blend described below containing 300 ppm DBTDL and having a thickness of 18 mils Component D was compression molded at 190° C. for 5 minutes into 18 mil films (0.018 inch, 457 micron). The Component D blend was composed of:

70 wt % ENGAGE™ elastomer blend Component A containing grafted trialkoxysilane groups and

30 wt % of unmodified ENGAGE EG8100 elastomer containing 1000 ppm of dibutyltin dilaurate (DBTDL).

These films were stored for approximately two days at ambient lab conditions then laminated to glass using a vacuum laminator with the following conditions: 5 minute degassing at 150° C., 10 minutes with full pressure at 150° C. After lamination, adhesion was tested using the 180-degree peel test, and then the gel content of the films was measured. The results are shown in the table below.

TABLE 2
Peel test results and gel fraction data for glass-laminated films

| | Layer | | | Gel |
|---|---|---|---|---|
| Film Number | structure | Catalyst conc | Peel Test (N/cm) | Fraction |
| 6 | A-glass | 0 | No delamination | 8% |
| 7 | D-glass | 300 ppm | 0.68 | 68% |

The results indicate that, when film component D, which contained the liquid catalyst DBTDL, cross-linked during the film preparation process and lamination processes, thus has very low adhesion to glass. However, when film component A, which did not contain DBTDL, was laminated directly to glass, adhesion was acceptable and crosslink levels at that point were low (8% gel fraction).

### Experimental Films 8-12

Multilayer films according to the present invention are prepared comprising distannoxane compound 1,3-diacetoxy-1,1,3,3-tetrabutyldistannoxane (melting point 56-58° C.) and dibutyltin maleate (melting point of about 135 to 140° C.) as the cross-linking catalysts. The thermoplastic polyolefin copolymer used was Polyolefin Copolymer, ENGAGE® 8200 brand copolymer (available from The Dow Chemical Company), as described above. The polyolefin copolymer is mixed with: 100 ppm of IRGANOX 1076® antioxidant (octadecyl 3,5-di-(tert)-butyl-4-hydroxyhydrocinnamate)) available from Ciba Specialties Chemicals Corporation, and several other additives identified in Table 1. The components A, E and F are used to prepare Experimental Films 8-12.

Component A: as described above, a silane-functionalized copolymer.

Components E and F: Cross-linking catalyst-containing carrier polyolefin copolymers are prepared from ENGAGE™ 8200 brand thermoplastic polyolefin copolymer comprising the cross-linking catalysts and amounts indicated below by mixing the catalyst and the copolymer in the melt in an extruder.

E1—100 ppm 1,3-diacetoxy-1,1,3,3-tetrabutyldistannoxane

E2—300 ppm 1,3-diacetoxy-1,1,3,3-tetrabutyldistannoxane

F—100 ppm dibutyltin maleate.

Multi-layer films were made feeding Copolymer Component A and either Copolymer Component E or F to dual extruders feeding a coextrusion feedblock or a coextrusion feedblock with a layer multiplier and film die attached that produced coextruded multi-layer structures of 5, 7, and 27 layers. For all the Experimental Films both of the exterior (skin) layers were silane-functionalized copolymer (Copolymer A) layers which skin layers had interior facial surfaces in adhering contact with facial surfaces of adjacent catalyst-containing (Copolymer E or F) layers. Then, depending upon the numbers of layers generated, there are additional siloxane layers that alternate with additional catalyst layers. Thus, Experimental Films 8 and 9 were provided having 5 layers having the layer sequences A-E-A-E-A and A-F-A-F-A. Experimental Film 10 had the layer sequence: A-F-A-F-A-F-A. Experimental Films 11 and 12 had 27 layers with more, thinner layers in the same Component A skin layers and alternating layer sequence based on Copolymers F and E, respectively. In these layered film structures, it can be sent that the catalyst-containing copolymer layers are sandwiched between silane-functionalized copolymer (Copolymer A) layers and have facial surfaces in adhering contact with facial surfaces of the adjacent silane-functionalized copolymer layers.

The extruders operate at 204 C at a feed rate of 20 lb/h. The residence time in the extruder and die was approximately 2 minutes. The overall thickness of the film was approximately 0.018 inch (457 micron).

Table 3 below describes Examples 8 through 12. For the experimental films the columns contain the following information:
the number of layers in the multi-layer film;
the weight ratio of the total weight of alkoxysilane-containing copolymer layers (“A Layers”) to the total weight of the cross-linking catalyst-containing copolymer layers (“E or F layers”) in the film;
the catalyst-containing copolymer component (E or F) layers that were alternated with alkoxysilane-containing copolymer layers;
initial concentration of the catalyst in the catalyst-containing component;
the adhesion strength of the multi-layer film after being laminated to glass;
the gel fraction of the multi-layer film after being exposed to lamination conditions.

Adhesion to glass was determined by a 180° peel test at ambient temperature using an Instron 5566 machine with a load rate of 2 in/min. The test samples were prepared by placing the film on the top of a sheet of regular, untreated glass under pressure in a lamination machine. The desired adhesion width was 1.0″. A Teflon sheet was placed between the glass and the material to separate the glass and polymer for the purpose of test setup. The lamination conditions for the glass/film samples were:
1. 150° C. for 5 min at 0 atm;
2. 150° C. for 2 min at 50% atm pressure;
3. 150° C. for 10 min at 100% atm pressure;
4. Remove the sample from the chase and allow 48 hr for the material to condition at room temperature before the adhesion test.

Gel fractions were determined as described above.

TABLE 3
Example Films 8-12

| | | Weight Ratio of | Catalyst- | Initial Catalyst | Adhesion | |
|---|---|---|---|---|---|---|
| | No. of | A Layers to | Containing | Conc in E | To Glass, | Gel |
| Example | Layers | E or F Layers | Copolymer | or F Layer | N/cm | Fraction |
| 8 | 5 | 50/50 | E1 | 100 ppm | 32.2 | 40% |
| 9 | 5 | 50/50 | E2 | 300 ppm | 34.8 | 42% |
| 10 | 7 | 70/30 | F | 300 ppm | No delam | 33% |
| 11 | 27 | 70/30 | F | 300 ppm | No delam | 41% |
| 12 | 27 | 70/30 | E1 | 100 ppm | No delam | 41% |

The data in Table 3 above clearly show that the multi-layer film adheres well to glass after being laminated and has reached sufficient gel fraction to have dimensional stability at high temperatures.

Although the invention has been described in considerable detail through the preceding description, drawings and examples, this detail is for the purpose of illustration. One skilled in the art can make many variations and modifications without departing from the spirit and scope of the invention as described in the appended claims. All United States patents and published or allowed United States patent applications referenced above are incorporated herein by reference.

What is claimed is:

1. A torque limiting fluid connector system, comprising:
an outer member having a front opening, a back opening, and a plurality of outwardly flexible portions separated by axially extending slots;
an inner member having a front opening, a back opening, an interior threaded surface and a plurality of outwardly extending projections dimensioned to be received within the axially extending slots when the inner member is received within the outer member;
a connector having one end received within the inner member and an opposite end extending out of the back end of the inner member; and
a washer mounted onto the end of the connector that is received within the inner member.

2. The system of claim 1, wherein the outwardly extending projections are received within the axially extending slots such that when a maximum tightening torque is reached, the plurality of outwardly flexible portions flex outwardly and slip over the outwardly extending projections to prevent the maximum tightening torque from being exceeded.

3. The system of claim 2, wherein the plurality of outwardly flexible portions do not flex outwardly and slip over the outwardly extending projections when a loosening torque is applied.

4. The system of claim 1, wherein the axially extending slots extend only partially along the axial length of the outer member.

5. The system of claim 1, wherein each of the outwardly flexible portions of the outer member extend circumferentially around a portion of the inner member.

6. The system of claim 5, wherein each of the outwardly flexible portions of the outer member have a leading edge at one of the axially extending slots and a trailing edge at another of the axially extending slots.

7. The system of claim 6, wherein the leading edge of each of the outwardly flexible portions is angled inwardly more than the trailing edge.

8. The system of claim 7, wherein each of the outwardly extending projections has an inwardly angled edge and a flat radially extending edge.

9. The system of claim 8, wherein the leading edge of the outwardly flexible portions push against the inwardly angled edge of the outwardly extending projections when a tightening torque is applied to the outer member.

10. The system of claim 8, wherein the leading edge of the outwardly flexible portions push against the flat radially extending edge of the outwardly extending projections when a loosening torque is applied to the outer member.

11. The system of claim 1, wherein the washer has a maximum axial thickness next to the connector, and a minimum axial thickness furthest away from the connector.

12. The system of claim 11, wherein the washer has a truncated conical shape.

13. The system of claim 11, wherein the inner member has a grooved recess at its back end adjacent to its interior threaded surface, and wherein the thinnest portion of the washer is received against the grooved recess when the washer is positioned flush against a rear wall of the inner member.

14. The system of claim 1, further comprising:
a fluid line connected to the end of the connector that extends out of the back end of the inner member.

15. The system of claim 14, wherein the fluid line is a liquid fluid line.

16. The system of claim 14, wherein the fluid line is a gas fluid line.

17. The system of claim 14, further comprising:
a shell positioned around an end of the fluid line, wherein the shell has a flattened end positioned against the back end of the outer member.

18. A method of connecting a fluid line to an object, comprising:
(a) providing a fluid line having a connector on one end, wherein the connector comprises:
(i) an outer member having a front opening, a back opening, and a plurality of outwardly flexible portions separated by axially extending slots;
(ii) an inner member having a front opening, a back opening, an interior threaded surface and a plurality of outwardly extending projections dimensioned to be received within the axially extending slots when the inner member is received within the outer member;
(iii) a connector having one end received within the inner member and an opposite end extending out of the back end of the inner member; and
(iv) a washer mounted onto the end of the connector that is received within the inner member;
(b) applying a tightening torque to the outer member such that the outer member applies a tightening torque to the inner member causing the inner member to rotate such that the interior threaded surface of the inner member threads onto the object;
(c) continuing to apply the tightening torque until a pre-set maximum tightening torque has been reached, wherein the inner member stops rotating and the outer member continues to rotate with the outwardly flexible portions of the outer member flexing outwardly and slipping over the outwardly extending projections on the inner member.

19. The method of claim 18, wherein the outwardly flexible portions of the outer member flex outwardly and slip over the outwardly extending projections on the inner member to prevent a pre-set tightening torque from being exceeded.

20. The method of claim 18, wherein the object is a pipe.

21. The method of claim 18, wherein the object is a toilet tank.

22. A method of disconnecting a fluid line from an object, comprising:
connecting the fluid line to the object using the method of claim 18; and then
(d) applying a loosening torque to the outer member such that the outer member applies a loosening torque to the inner member causing the inner member to rotate such that the interior threaded surface of the inner member unthreads from the object.

23. The method of claim 22, wherein the loosening torque is greater than the tightening torque.

24. The method of claim 22, wherein the outwardly flexible portions of the outer member do not flex outwardly and do not slip over the outwardly extending projections on the inner member when the loosening torque is applied.
